(19) United States
(12) Patent Application Publication
(10) Pub. No.: US 2013/0328169 A1
(43) Pub. Date: Dec. 12, 2013

(54) RESISTIVE DEVICE AND METHOD OF MANUFACTURING THE SAME

(71) Applicant: Fairchild Korea Semiconductor Ltd., Bucheon-si (KR)

(72) Inventor: Jung-hyun CHOI, Incheon (KR)

(21) Appl. No.: 13/915,501

(22) Filed: Jun. 11, 2013

(30) Foreign Application Priority Data
Jun. 12, 2012 (KR) 10-2012-0062858

(51) Int. Cl. H01L 49/02

(52) U.S. Cl. CPC H01L 28/20
USPC 257/537; 438/382

(57) ABSTRACT

This disclosure is related to a resistive device including a silicide pattern. A resistive device can include a substrate, and a first resistive layer disposed above the substrate. The resistive device can include a second resistive layer disposed on the first resistive layer and has a resistance different from a resistance of the first resistive layer. The resistive device can include a third resistive layer disposed on a first portion of the first resistive layer such that a second portion of the first resistive layer is disposed between the third resistive layer and the second resistive layer. The resistive layer can also include a conductive plug electrically connected to the third resistive layer.

### CROSS-REFERENCE TO RELATED APPLICATION

This application claims priority to and the benefit of Korean Patent Application No. 10-2012-0062858, filed on Jun. 12, 2012, in the Korean Intellectual Property Office, the disclosure of which is incorporated by reference herein in its entirety.

### TECHNICAL FIELD

This disclosure is related to a semiconductor device, and more particularly, to a resistive device and a method of manufacturing the same.

### BACKGROUND

Semiconductor devices include various devices, such as a resistive device, in addition to transistor structures. In general, a conventional resistive device is formed of a semiconductor layer doped with impurities, where a resistance of the resistive device varies according to a size of the resistive device. In order to form the conventional resistive device, there is a need to change a layout design to obtain a desired resistance. Thus, it is difficult to change the resistance and also costly because a new mask is required.

### SUMMARY

The disclosure describes a resistive device including a silicide pattern, and a method of manufacturing the same.

According to at least one general aspect, a resistive device can include a substrate, and a first resistive layer disposed above the substrate. The resistive device can include a second resistive layer disposed on the first resistive layer and has a resistance different from a resistance of the first resistive layer. The resistive device can include a third resistive layer disposed on a first portion of the first resistive layer such that a second portion of the first resistive layer is disposed between the third resistive layer and the second resistive layer. The resistive layer can also include a conductive plug electrically connected to the third resistive layer.

### BRIEF DESCRIPTION OF THE DRAWINGS

Exemplary embodiments of the disclosure can be more clearly understood from the following detailed description taken in conjunction with the accompanying drawings in which:

FIG. 1 is a cross-sectional view of a resistive device according to an embodiment;

FIG. 2 is a plan view of the resistive device of FIG. 1 taken along line II-II;

FIG. 3 is a plan view of the resistive device of FIG. 1 taken along line III-III;

FIG. 4 is a cross-sectional view for describing a resistance of the resistive device of FIG. 1;

FIGS. 5 to 9 are plan views showing a first resistive layer and a second resistive layer of the resistive device of FIG. 1 according to embodiments;

FIGS. 10 and 11 are cross-sectional views respectively showing resistive device arrays in which a plurality of resistive devices are arranged, according to embodiments; and

FIGS. 12 to 22 are cross-sectional views for describing a method of manufacturing the resistive device of FIG. 1, according to an embodiment.

### DETAILED DESCRIPTION

Exemplary embodiments will now be described more fully with reference to the accompanying drawings. The embodiments may be in many different forms and should not be construed as being limited to the embodiments set forth herein; rather, these embodiments are provided so that this disclosure will be thorough and complete, and will fully convey the concept to those skilled in the art.

As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. In diagrams, like reference numerals in the drawings denote like elements. In addition, various elements and regions are schematically shown in diagrams. Thus, embodiments are not limited to relative sizes and intervals shown in diagrams. As used herein, the term “and/or” includes any and all combinations of one or more of the associated listed items. Expressions such as “at least one of,” when preceding a list of elements, modify the entire list of elements and do not modify the individual elements of the list.

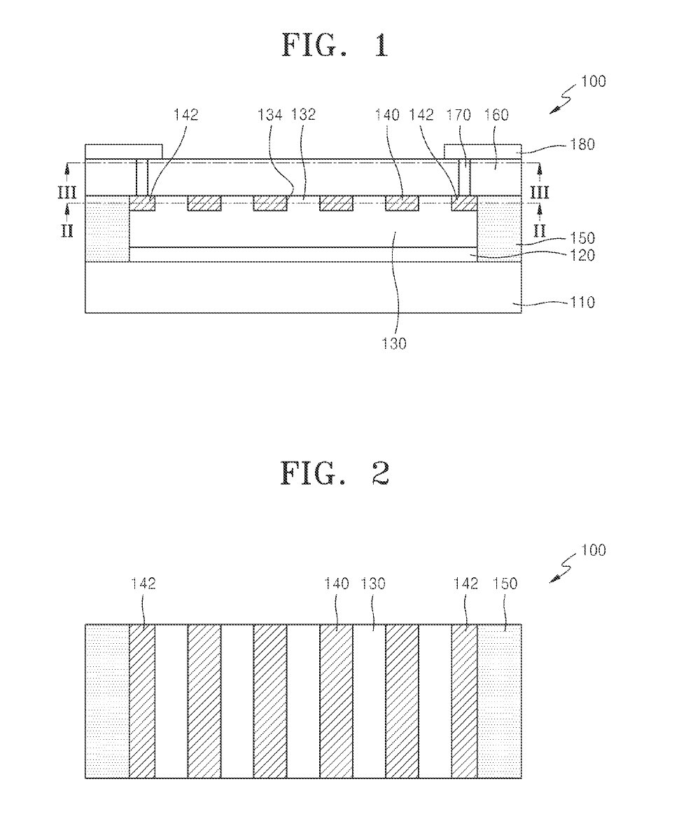

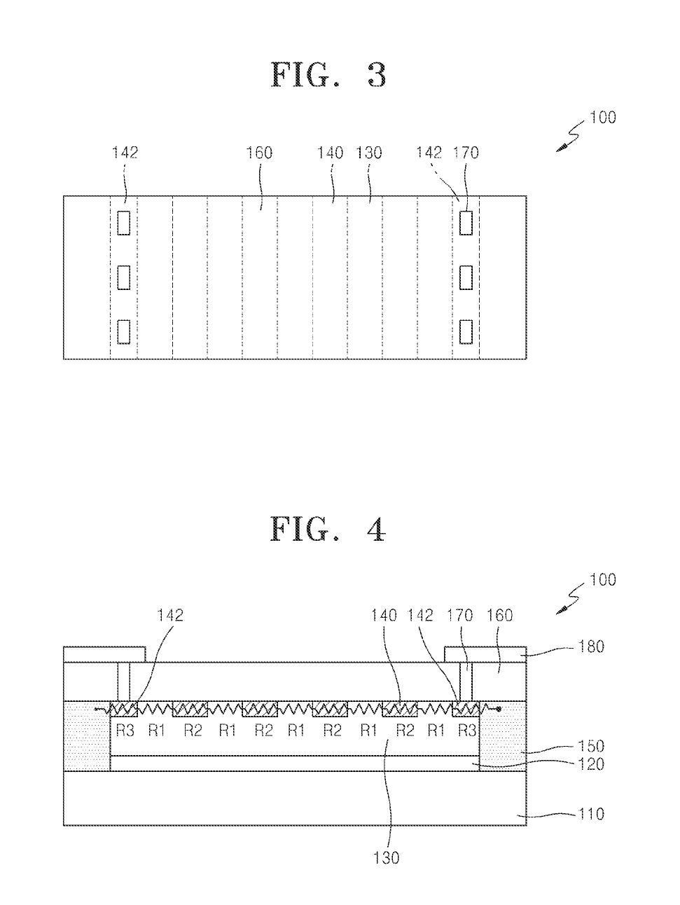

FIG. 1 is a cross-sectional view of a resistive device 100 according to an embodiment. FIG. 2 is a plan view of the resistive device 100 of FIG. 1 taken along line II-II. FIG. 3 is a plan view of the resistive device 100 of FIG. 1 taken along line III-III. In FIG. 3, components disposed below a surface are shown as a dashed line. A direction from the top of FIG. 1 to the bottom of FIG. 1 (or vice versa) can be referred to as a vertical direction. Components along the vertical direction can be referred to as being vertically stacked (e.g., vertically above, vertically below). A direction that is orthogonal to the vertical direction (along line II-II or along line III-III) can be referred to as a horizontal direction or as a lateral direction. Accordingly, elements can be disposed lateral to, or horizontal to, other elements. The plan views can be aligned along, or disposed within, a plane. Similar vertical directions and horizontal directions can be applied to all of the figures in this disclosure.

Referring to FIGS. 1 to 3, the resistive device 100 includes a substrate 110, a first insulating interlayer 120, a first resistive layer 130, a second resistive layer 140, a second insulating interlayer 150, a third insulating interlayer 160, a conductive plug 170, and a conductive terminal 180.

The substrate 110 may include a semiconductor layer formed of silicon (Si), silicon-germanium (SiGe), and/or silicon carbide (SiC). Also, the substrate 110 may include an epitaxial layer, a silicon-on-insulator (SOI) layer, and/or a semiconductor-on-insulator (SEOI) layer. Although not shown in FIG. 1, the substrate 110 may include various wiring lines or may further include different kinds of semiconductor devices such as a transistor. Also, the substrate 110 may further include a conductive layer formed of titanium (Ti), titanium nitride (TiN), aluminum (Al), tantalum (Ta), tantalum nitride (TaN), and/or titanium aluminum nitride (TiAlN). Alternatively, the substrate 110 may further include a dielectric layer formed of silicon oxide, titanium oxide, aluminum oxide, zirconium oxide, or hafnium oxide.

The first insulating interlayer 120 is disposed on at least a part (e.g., a portion) of the substrate 110. The first insulating interlayer 120 may include at least one of oxide, nitride, and oxynitride. The first insulating interlayer 120 may include at least one of, for example, silicon oxide, silicon nitride, and silicon oxynitride. Alternatively, the first insulating interlayer 120 may extend on the entire substrate 110. For example, the first insulating interlayer 120 can have a surface area equal to (e.g., substantially equal to) a surface area of the substrate 110. In such embodiments, at least some portions of the second insulating interlayer 150 can be insulated from the substrate 110 by the first insulating interlayer 120. In some implementations, the first insulating interlayer 120 can function as a resistive layer having a relatively large resistance.

The first resistive layer 130 is disposed on the first insulating interlayer 120 such that the first insulating interlayer 120 is disposed between the substrate 110 and the first resistive layer 130. The first resistive layer 130 includes a protrusion region 132 formed at an upper side of the first resistive layer 130, and includes a recessed region 134 formed between the protrusion region 132 and another protrusion region (not labeled). Accordingly, the protrusion region 132 can define a sidewall of the recessed region 134. The first resistive layer 130 may include a semiconductor material, for example, a Group IV semiconductor material. The first resistive layer 130 may include, for example, silicon, silicon-germanium, or germanium. Also, the first resistive layer 130 may include a single-crystal material or a polycrystalline material. The first resistive layer 130 may include, for example, polysilicon. The first resistive layer 130 may also include impurities such as an n-type conductive material or a p-type conductive material. The n-type conductive material may include a Group V element or a Group VI element. For example, the n-type conductive material may include nitrogen, phosphorus, arsenic, stibium, or the like. The p-type conductive material may include a Group III element or a Group IV element. For example, the p-type conductive material may include boron (B), Al, gallium (Ga), indium (In), or the like.

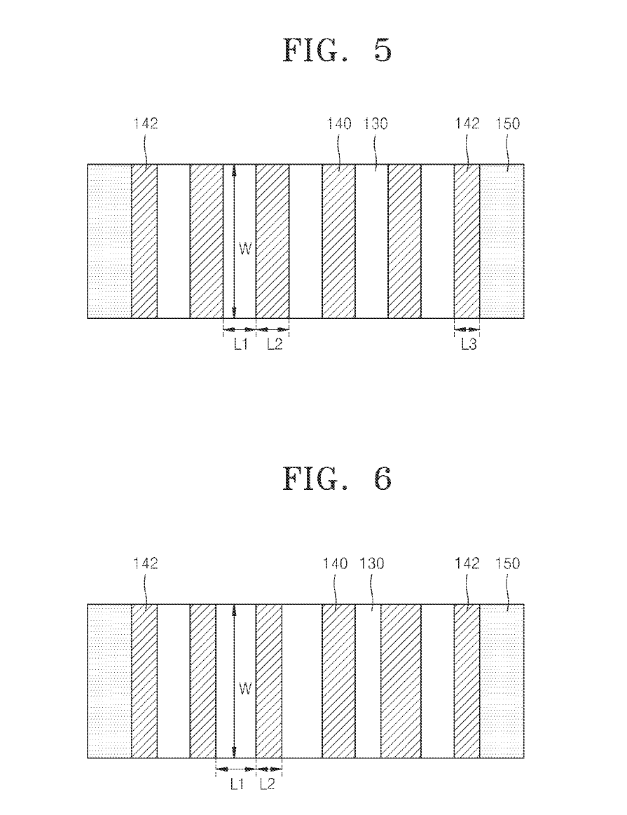

The second resistive layer 140 is disposed within (e.g., embedded within, recessed within, disposed on) at least a part (or portion) of the first resistive layer 130, for example, inside the recessed region 134. Portions (or stripes) of the second resistive layer 140 are lateral to (e.g., interleaved between) portions (or stripes) of the first resistive layer 130. The first resistive layer 130 may be at least one region or portion. The second resistive layer 140 may be at least one region or portion. An uppermost surface (also can be referred to as a top surface) of the first resistive layer 130 and an uppermost surface of the second resistive layer 140 may be on the same plane (or coplanar). Accordingly, a top surface of the protrusion 132 can be coplanar (e.g., substantially coplanar) with a portion (also can be referred to as a stripe) of the second resistive layer 140 disposed within the recessed region 134 (which can also be referred to as a trench). The protrusion region 132 and the recess region 132 can define an interface between a portion of the first resistive layer 130 and a portion of the second resistive layer 140. As shown in FIG. 1, at least a first portion of the first resistive layer 130 is disposed below (e.g., vertically disposed below) the second resistive layer 140 (disposed (e.g., vertically disposed) between the second resistive layer 140 and the substrate 110 and/or the first insulating interlayer 120). In other words, at least a portion of the second resistive layer 140 is disposed on the first portion of the first resistive layer 130. Also, a second portion of the first resistive layer 130 is disposed between pairs of portions of the second resistive layer 140. Exemplary locations of the first resistive layer 130 and the second resistive layer 140 will be described below with reference to FIGS. 5 to 9.

The second resistive layer 140 may include a material having a resistance (which can be a resistivity (e.g., resistance per square or resistance per length), an overall resistance, etc.) lower than that of a material for forming the first resistive layer 130. The second resistive layer 140 may include a material formed by reacting the material forming the first resistive layer 130 with a metal material. The second resistive layer 140 may include a silicide material, for example, a metal silicide material. The metal may include any one of titanium (Ti), cobalt (Co), nickel (Ni), tantalum (Ta), platinum (Pt), vanadium (V), erbium (Er), zirconium (Zr), hafnium (Hf), molybdenum (Mo), and ytterbium (Yb).

In this embodiment, portions (also can be referred to as stripes) of a third resistive layer 142 are disposed on two edges (e.g., opposite edges or edge portions) of the first resistive layer 130. The third resistive layer 142 can be referred to as being disposed within the first resistive layer 130.

Specifically, a first portion of the third resistive layer 142 has a first edge (shown as a right edge or as a vertical edge) aligned along (e.g., vertically aligned along within a same plane) a first edge (shown as a right edge) of the first resistive layer 130. Also, a second portion of the third resistive layer 142 has a first edge (shown as a left edge or as a vertical edge) aligned along (e.g., vertically aligned along within a same plane) a second edge (shown as a left edge) of the first resistive layer 130. As oriented, the first portion of the third resistive layer 142 is vertically disposed above a first portion (e.g., an edge portion) of the first resistive layer 130 and a second portion of the first resistive layer 130 is laterally disposed between the first portion of the third resistive layer 142 and a portion of the second resistive layer 140. Accordingly, the first portion of the third resistive layer 142 is disposed within (e.g., embedded within, recessed within) the first resistive layer 130. Also, as shown in FIG. 1, the first edge of the first portion of the third resistive layer 142 abuts or is in contact with a first portion (on the right of the cross-sectional view) of the second insulating interlayer 150, and the first edge of the second portion of the third resistive layer 142 abuts or is in contact with a second portion (on the left of the cross-sectional view) of the second insulating interlayer 150. The third resistive layer 142 can be considered as being different from the first resistive layer 130 or the second resistive layer 140 because the third resistive layer 142 is coupled to the conductive plug 170. At least some portions of the third resistive layer 142 can be insulated from (e.g., non-abutting) the second insulating interlayer 150. The third resistive layers 142 may include a material that is the same as the material for forming the second resistive layer 140. A resistance (or resistivity) of the third resistive layer 142 may be the same as that of the second resistive layer 140. Also, the third resistive layer 142 (or one or more portions thereof) may have a size (e.g., a surface area with a length and width) that is the same as or different from a size (e.g., a surface area with a length and width) of the second resistive layer 140 (or one or more portions thereof).

The second insulating interlayer 150 may be disposed on the substrate 110. The second insulating interlayer 150 is in contact with or abuts at least one lateral wall (also can be referred to as a sidewall or vertical wall) of the first insulating interlayer 120. Also, the second insulating interlayer 150 is in contact with or abuts at least one lateral wall of the first resistive layer 130. The second insulating interlayer 150 may be lateral to (e.g., horizontal to) or may abut the third resistive layer 142. The second insulating interlayer 150 may include at least one of oxide, nitride, and oxynitride, for example, at least one of silicon oxide, silicon nitride, and silicon oxynitride. The first insulating interlayer 120 and the second insulating interlayer 150 may include the same material or different materials.

The third insulating interlayer 160 may be disposed on (or vertically above) the first resistive layer 130 and the second resistive layer 140. In such instances the third insulating interlayer 160 can contact a top surface of the first resistive layer 130 and a top surface of the second resistive layer 140. Also, in such embodiments, a bottom surface of the third insulating interlayer 160 can be planar (e.g., substantially planar). The third insulating interlayer 160 may also be disposed on (e.g., disposed above or vertically above, extend on) the second insulating interlayer 150. The third insulating interlayer 160 may include at least one of oxide, nitride, and oxynitride, for example, at least one of silicon oxide, silicon nitride, and silicon oxynitride. The first insulating interlayer 120, the second insulating interlayer 150, and/or the third insulating interlayer 160 may include the same material or different materials.

The conductive plug 170 may be disposed in (e.g., penetrate) the third insulating interlayer 160 and may be physically and/or electrically connected to the third resistive layer 142. The conductive plug 170 may include a conductive material such as a metal, for example, Al, copper (Cu), tungsten (W), Ti, or Ta, or an alloy such as titanium tungsten (TiW) or titanium aluminum (TiAl). Although FIGS. 2 and 3 show three conductive plugs 170, this just an example, and the shape of the conductive plugs 170 or the number of conductive plugs 170 may vary.

The conductive terminal 180 may be disposed on the third insulating interlayer 160 and may be physically and/or electrically connected to the conductive plug 170. The conductive terminal 180 may include a conductive material such as a metal, for example, Al, Cu, W, Ti, or Ta, or an alloy such as TiW or TiAl. The conductive plug 170 and the conductive terminal 180 may include the same material or different materials. The conductive plug 170 can be configured so that the conductive plug 170 extends between the conductive terminal 180 and the third resistive layer 142.

FIG. 4 is a cross-sectional view for describing a resistance of the resistive device 100 of FIG. 1.

Referring to FIG. 4, the resistance of the resistive device 100 may be represented by Equation 1. A total resistance R_{T} of the resistive device 100 may be obtained by multiplying a resistance-related function f(Rᵢ) of the first resistive layer 130 and the second resistive layer 140, a temperature-related function f(T) of the first resistive layer 130 and the second resistive layer 140, and a voltage-related function f(V) of the first resistive layer 130 and the second resistive layer 140.

R_{T}=ƒ(Rᵢ)·ƒ(T)·ƒ(V) (1)

In detail, the resistance of the resistive device 100 may be represented by Equation 2, wherein the subscript ‘1’ represents a variable (or number) corresponding to the first resistive layer 130, the subscript ‘2’ represents a variable (or number) corresponding to the second resistive layer 140, and the subscript ‘3’ represents a variable (or number) corresponding to the third resistive layer 142.

$${R}_{T} = [ \sum {R}_{1} \cdot \frac{{L}_{1} - 2 Δ {L}_{1}}{{W}_{1} - 2 Δ {W}_{1}} ] \cdot [ 1 + T C {R}_{1} \cdot 1 \cdot ( T - {T}_{0} ) + T C {R}_{1} \cdot 2 \cdot {( T - {T}_{0} )}^{2} ] \cdot [ 1 + V C {R}_{1} \cdot 1 \cdot Δ V + V C {R}_{1} \cdot 2 \cdot Δ {V }^{2} ] + [ \sum {R}_{2} \cdot \frac{{L}_{2} - 2 Δ {L}_{2}}{{W}_{2} - 2 Δ {W}_{2}} + 2 {R}_{3} ] \cdot [ 1 + T C {R}_{2} \cdot 1 \cdot ( T - {T}_{0} ) + T C {R}_{2} \cdot 2 \cdot {( T - {T}_{0} )}^{2} ] \cdot [ 1 + V C {R}_{2} \cdot 1 \cdot Δ V + V C {R}_{2} \cdot 2 \cdot Δ {V}^{2} ] \qquad ( 2 )$$

where, R₁, R₂, and R₃ each represent (or denote) a resistance, L₁ and L₂ each represent (or denote) a length, W₁ and W₂ each represent (or denote) a width, T represents (or denotes) an operating temperature, T₀ represents (or denotes) an initial temperature, TC represents (or denotes) a temperature coefficient, and V represents (or denotes) an application voltage. Changes in values are represented with the symbol Δ. Different embodiments of the lengths (e.g., length L₁) and widths (e.g., W₁) that can be used in the equations (1) and (2) above are shown in connection with, for example, FIGS. 5 through 9.

Thus, the resistance of the resistive device 100 may be changed by changing the size (e.g., length and/or width) and number of second resistive layers 140 (which can affect the number of first resistive layers 130).

FIGS. 5 to 9 are plan views showing portions of the first resistive layer 130, portions of the second resistive layer 140, and portions of the third resistive layer 142 of the resistive device 100 of FIG. 1 according to other embodiments.

Referring to FIG. 5, portions (also can be referred to as stripes) of the first resistive layer 130 are alternately disposed with (or interleaved with) portions of the second resistive layer 140. Also, at least two portions of the third resistive layer 142 are spaced apart from each other with the first resistive layer 130 and the second resistive layer 140 disposed therebetween. The length L₁ of each portion of the first resistive layer 130 may be the same or equal. Also, the length L₂ of each portion of the second resistive layer 140 may be the same or equal. In other words, portions of the second resistive layer 140 may have the same length or equal and may be spaced apart from one another at the equal intervals. Portions of the second resistive layer 140 may have the same length and may be spaced apart from one another at the equal intervals by portions of the first resistive layer 130. The length L₁ of portions of the first resistive layer 130 and the length L₂ of portions of the second resistive layer 140 may be the same as or different from each other. Also, since portions of the second resistive layer 140 each have the same width W in this embodiment, each of the portions of second resistive layers 140 may have the same area (e.g., surface area) (when viewed in plan view) or size. The length L₃ of one or more portions of the third resistive layer 142 may be the same as or different from the length L₁ of one or more portions of the first resistive layer 130 and/or the length L₂ of one or more portions of the second resistive layer 140. In this implementation (and other implementations shown and described herein), the width W extends from one side of the resistive device 100 to the opposite side of the resistive device 100.

Although in this embodiment portions of the third resistive layer 142 are insulated or separated from the portions of the second resistive layer 130 by portions of the first resistive layer 140, in some embodiments, one or more portions of the second resistive layer 130 can be in contact with one or more portions of the third resistive layer 142. Although the aspect ratios illustrate that the lengths are generally smaller than the widths, in some implementations, the widths can be greater than or equal to the lengths.

Referring to FIG. 6, portions of the first resistive layer 130 are alternately disposed with (or interleaved with) portions of the second resistive layer 140. Also, at least two portions of the third resistive layer 142 are spaced apart from portions of the second resistive layer 140 with portions of the first resistive layers 130 therebetween. The lengths L₁ of portions of the first resistive layers 130 may be different (or unequal) from one another. Accordingly, a first portion of the first resistive layer 130 can have a length that is different than a length of a second portion of the first resistive layer 130. Also, the lengths L₂ of portions the second resistive layers 140 may be different (or unequal) from one another. Accordingly, a first portion of the second resistive layer 140 can have a length that is different than a length of a second portion of the second resistive layer 140. In other words, portions of the second resistive layer 140 may have different lengths and may be spaced apart from one another at different intervals (by the portions of the first resistive layer 130). Also, since each of portion of the second resistive layer 140 has the same width W, portions of the second resistive layer 140 may have different areas (e.g., surface area) (when viewed in plan view) or sizes. The arrangement of portions of the first resistive layer 130 and portions of the second resistive layer 140 is just an example, and thus, portions of the first resistive layer 130 and portions of the second resistive layer 140 may be arranged in various ways.

Although in this embodiment portions of the third resistive layer 142 are insulated or separated from the portions of the second resistive layer 130 by portions of the first resistive layer 140, in some embodiments, one or more portions of the second resistive layer 130 can be in contact with one or more portions of the third resistive layer 142.

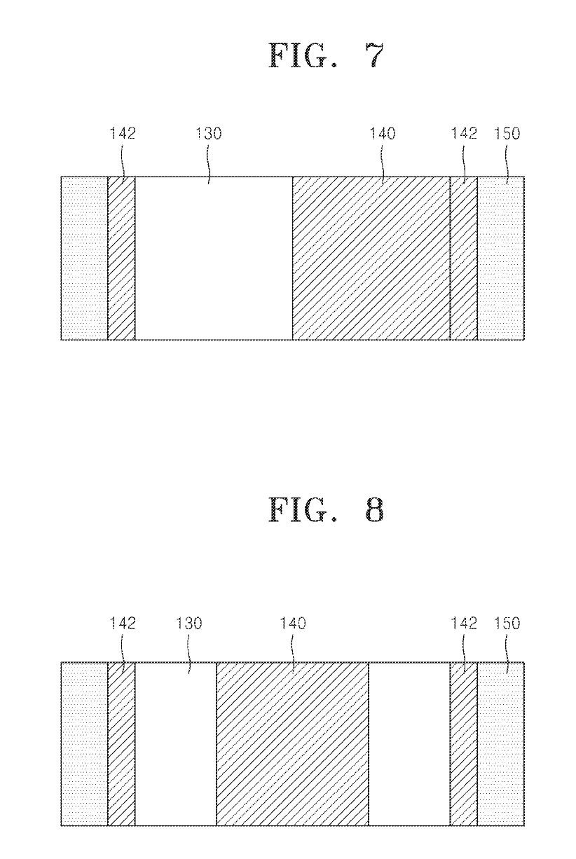

Referring to FIG. 7, in this embodiment, the first resistive layer 130 is disposed at a first side, and the second resistive layer 140 is disposed at a second side. The second resistive layer 140 and the first resistive layer 130 may each include a single area. One portion of the third resistive layer 142 (on the first side) contacts the first resistive layer 130, and the other portion of the third resistive layer 142 (on the second side) contacts the second resistive layer 140. Although not shown in FIG. 8, in some embodiments, additional portions of the first resistive layer 130 and/or additional portions of the second resistive layer 140 can be disposed between the portions of the third resistive layer 142.

As shown in FIG. 7, the portion of the first resistive layer 130 and the portion of the second resistive layer 140 each have a surface area (when viewed from above as shown in FIG. 7) that is larger than a surface area of the each of the portions of the third resistive layer 142. In addition, the portion of the first resistive layer 130 and the portion of the second resistive layer 140 each have a surface area (when viewed from above) that is larger than a collective surface area of the portions of the third resistive layer 142. In some implementations, the portion of the first resistive layer 130 and/or the portion of the second resistive layer 140 can each have a surface area that is equal to or less than a surface area of the each of the portions of the third resistive layer 142 and/or a collective surface area of the portions of the third resistive layer 142.

Referring to FIG. 8, portions of the first resistive layer 130 are disposed at two sides of the second resistive layer 140. The second resistive layer 140 may include a single area. Portions of the third resistive layer 142 contact the portions of first resistive layer 130. The second resistive layer 140 may be spaced apart from (e.g., insulated from, separated from) the third resistive layers 142. In other words, portions of the first resistive layer 130 are disposed between the single portion of the second resistive layer 140 and the portions of the third resistive layer 142.

As shown in FIG. 8, the portion of the first resistive layer 130 and the portion of the second resistive layer 140 each have a surface area (when viewed from above as shown in FIG. 8) that is larger than a surface area of the each of the portions of the third resistive layer 142. In addition, the portion of the first resistive layer 130 and the portion of the second resistive layer 140 each have a surface area that is larger than a collective surface area of the portions of the third resistive layer 142. In some implementations, the portion of the first resistive layer 130 and/or the portion of the second resistive layer 140 can each have a surface area that is equal to or less than a surface area of the each of the portions of the third resistive layer 142 and/or a collective surface area of the portions of the third resistive layer 142.

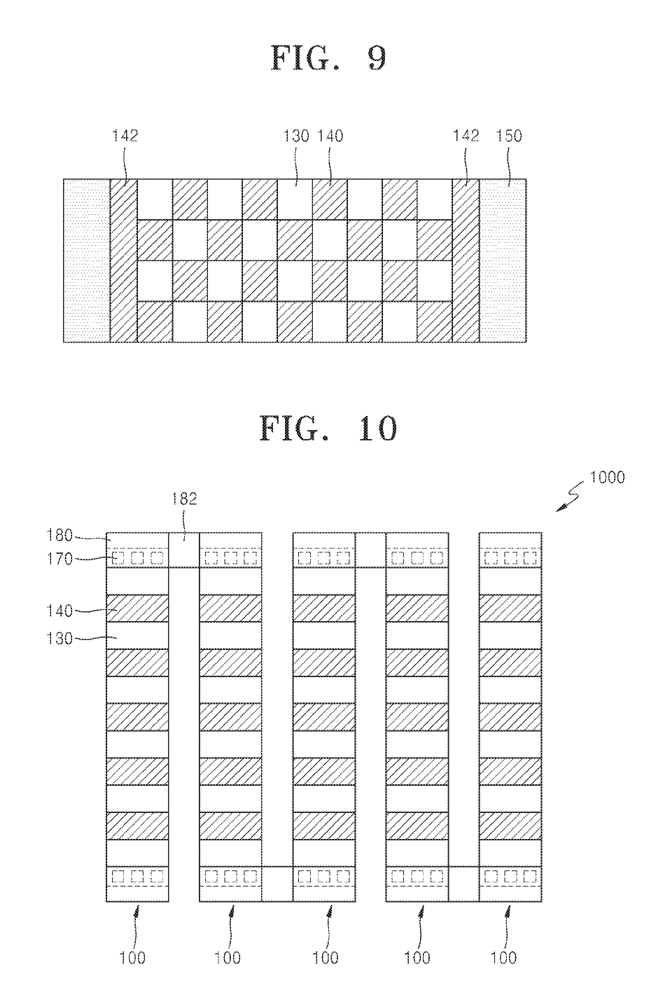

Referring to FIG. 9, portions of the first resistive layer 130 and portions of the second resistive layer 140 may be disposed symmetrical to each other. For example, portions of the first resistive layer 130 and portions of the second resistive layer 140 may be arranged in a checked pattern. For example, a portion of the second resistive layer 140 may be surrounded by multiple portions (on each of four sides) of the first resistive layer 130, and a portions of the first resistive layer 130 may be surrounded by multiple portions (on each of four sides) of the second resistive layer 140. The third resistive layers 142 may both contact portions of the first resistive layer 130 and contact portions of the second resistive layer 140.

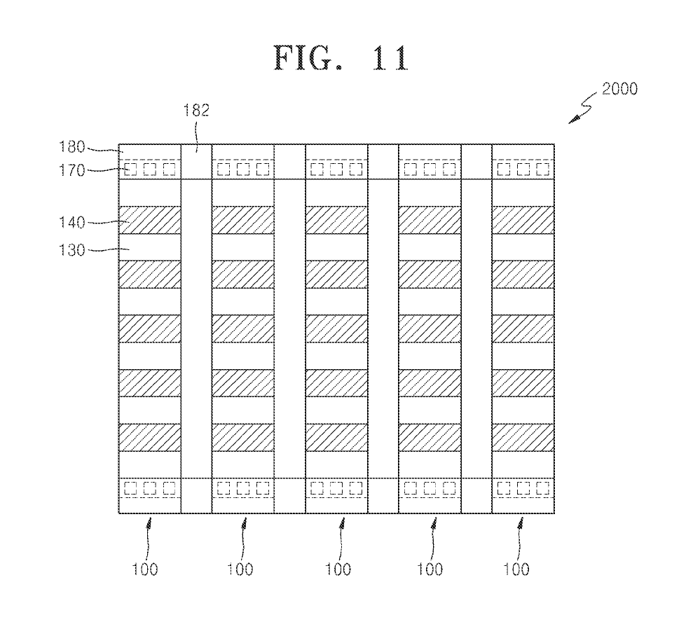

FIGS. 10 and 11 are cross-sectional views respectively showing resistive device arrays 1000 and 2000 in which a plurality of the resistive devices 100 are arranged according to embodiments.

Referring to FIG. 10, the resistive device array 1000 includes the plurality of resistive devices 100. The plurality of resistive devices 100 may be electrically connected to one another in series via a plurality of connection units 182. The connection unit 182 electrically connects the conductive terminal 180 of one of the plurality of the resistive devices 100 to the conductive terminal 180 of an adjacent or another of the plurality of resistive devices 100. Thus, the resistive device array 1000 having various resistances may be embodied through such an electrical connection. For example, as the number of plurality of resistive devices 100 connected to one another in series via the connection units 182 increases, a resistance of the resistive device array 1000 may be increased. Also, the resistance of the resistive device array 1000 may be changed by breaking any one of the connection units 182 (which can be performed during post-processing).

Referring to FIG. 11, the resistive device array 2000 includes the plurality of resistive devices 100. The plurality of resistive devices 100 may be electrically connected to one another in parallel via the connection units 182. The connection units 182 electrically connect the conductive terminal 180 of one of the plurality of resistive devices 100 to the conductive terminal 180 of an adjacent or another of the plurality of resistive devices 100. Thus, the resistive device array 2000 having various resistances may be embodied through such an electrical connection. For example, as the number of plurality of resistive devices 100 connected to one another in parallel via the connection units 182 increases, a resistance of the resistive device array 2000 may be decreased. Also, the resistance of the resistive device array 2000 may be changed by breaking any one of the connection units 182 (which can be performed during post-processing).

FIGS. 12 to 22 are cross-sectional views for describing a method of manufacturing, for example, the resistive device 100 of FIG. 1, according to an embodiment.

Referring to FIG. 12, the substrate 110 includes a first region I and a second region II. The first region I is a region where the resistive device 100, according to the embodiments, is formed. The second region II is a region where a power device, a memory device, a switching device, etc. are formed. In particular, the second region II is a region where transistors included in the power device, the memory device, the switching device, etc. are formed.

Next, the first insulating interlayer 120 is formed on the substrate 110. The first insulating interlayer 120 may include at least one of oxide, nitride, and oxynitride. For example, the first insulating interlayer 120 may include at least one of silicon oxide, silicon nitride, and silicon oxynitride. The first insulating interlayer 120 may be formed by thermal oxidation, sputtering, chemical vapor deposition (CVD), low pressure CVD (LPCVD), plasma-enhanced CVD (PECVD), atomic layer deposition (ALD), or the like.

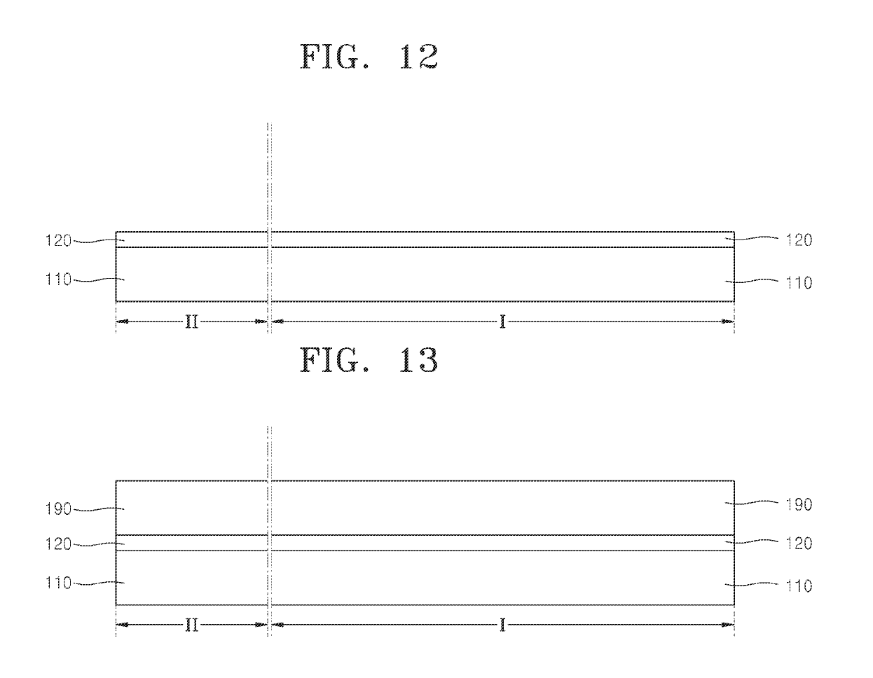

Referring to FIG. 13, a semiconductor layer 190 is formed on the first insulating interlayer 120. The semiconductor layer 190 may include a semiconductor material, for example, a Group IV semiconductor material. The semiconductor layer 190 may include, for example, silicon, silicon-germanium, or germanium. Also, the semiconductor layer 190 may include a single-crystal material or a polycrystal material. The semiconductor layer 190 may include, for example, polysilicon. The semiconductor layer 190 may be formed by sputtering, CVD, LPCVD, PECVD, ALD, or the like. Alternatively, the semiconductor layer 190 may be grown from the first insulating interlayer 120 using an epitaxial method.

Referring to FIG. 14, a first doped layer 192 is formed by doping the semiconductor layer 190 of the first region I with impurities (or dopants). This is illustrated by arrows in FIG. 14. Also, a second doped layer 194 is formed by doping the semiconductor layer 190 of the second region II with impurities.

The impurities included in the first doped layer 192 and/or the second doped layer 194 may include an n-type conductive material or a p-type conductive material. The n-type conductive material may include a Group V element or a Group VI element. For example, the n-type conductive material may include nitrogen, phosphorus, arsenic, stibium, or the like. The p-type conductive material may include a Group III element or a Group IV element. For example, the p-type conductive material may include boron, aluminum, gallium, indium, or the like.

The first doped layer 192 and/or the second doped layer 194 may be formed by forming an impurity layer (not shown) including the above-described impurities on the semiconductor layer 190 and then diffusing the impurities into the semiconductor layer 190 or injecting the impurities into the semiconductor layer 190 by ion injection. The first doped layer 192 and the second doped layer 194 may be formed in the same process or different processes.

The first doped layer 192 and the second doped layer 194 may include the same conductive impurities (or impurities of the same conductivity type). Alternatively, the first doped layer 192 and the second doped layer 194 may include different conductive impurities (or impurities of the different conductivity type). For example, the first doped layer 192 may include the p-type conductive material, and the second doped layer 194 may include the n-type conductive material, or vice-versa. If the first doped layer 192 includes the p-type conductive material, the first doped layer 192 may have a low mobility and high stability of impurities, and these characteristics of the first doped layer 192 may be effectively used in a resistive device. In addition, if the second doped layer 194 includes the n-type conductive material, the second doped layer 194 may have a high mobility and low stability of impurities, and these characteristics of the second doped layer 194 may be effectively used in a transistor device.

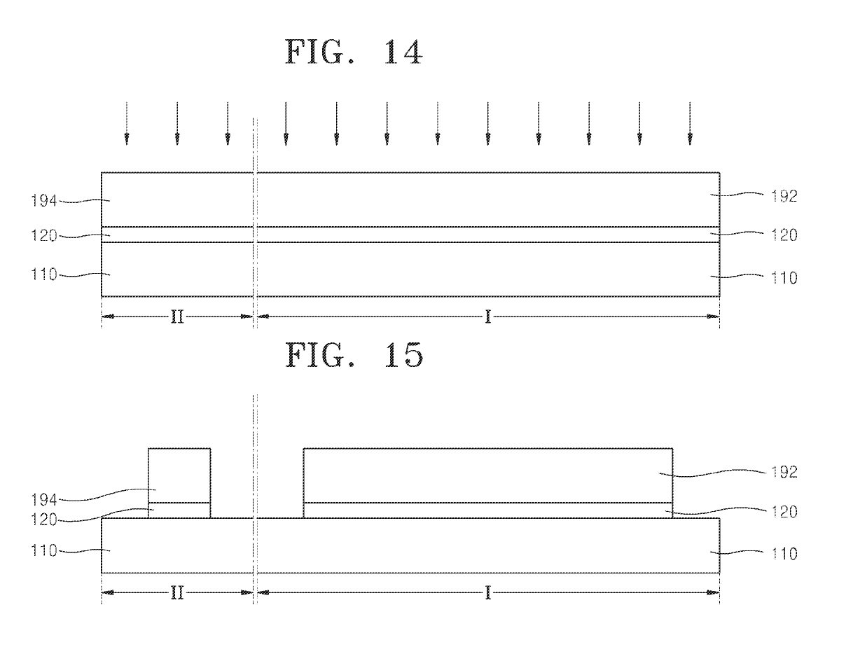

Referring to FIG. 15, a part (e.g., a portion) of the first doped layer 192 is removed in the first region I, and a part of the second doped layer 194 is removed in the second region II. Alternatively, a part of the first insulating interlayer 120 may be removed in the first region I and/or the second region II, and thus, the substrate 110 may be exposed. The removing process may be performed using a photolithography process and an etching process.

Referring to FIG. 16, the second insulating interlayer 150 is formed on the exposed substrate 110. The second insulating interlayer 150 may be disposed on (e.g., in contact with, abutting) one or more lateral walls (e.g., vertical walls, sidewalls) of the first insulating interlayer 120 and one or more lateral walls (e.g., vertical walls, sidewalls) of the first doped layer 192 in the first region I. Also, the second insulating interlayer 150 may be disposed on one or more lateral walls (e.g., vertical walls, sidewalls) of the first insulating interlayer 120 and the second doped layer 194 in the second region II. The second insulating interlayer 150 may include at least one of oxide, nitride, and oxynitride. For example, the second insulating interlayer 150 may include at least one of silicon oxide, silicon nitride, and silicon oxynitride. The second insulating interlayer 150 may be formed by sputtering, CVD, LPCVD, PECVD, ALD, or the like. The first insulating interlayer 120 and the second insulating interlayer 150 may include the same material or different materials.

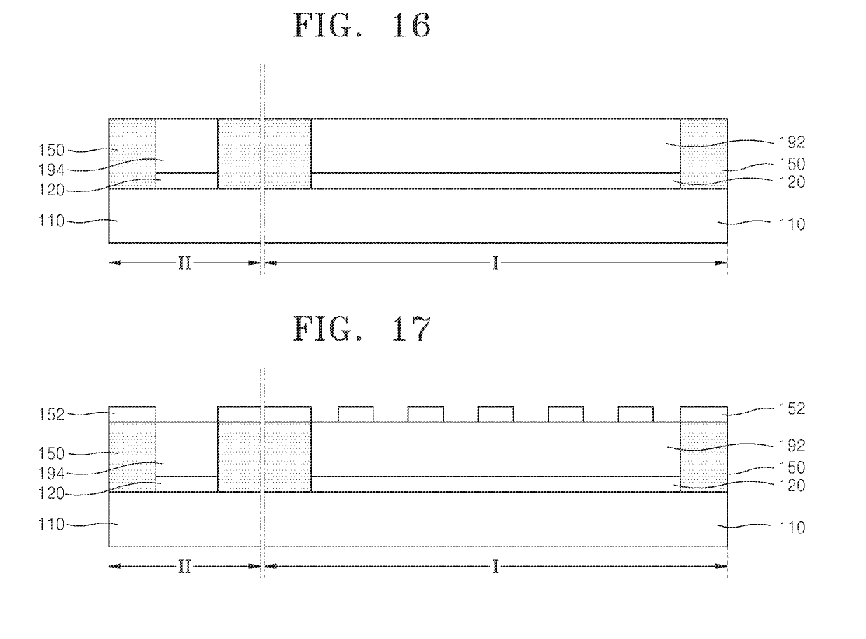

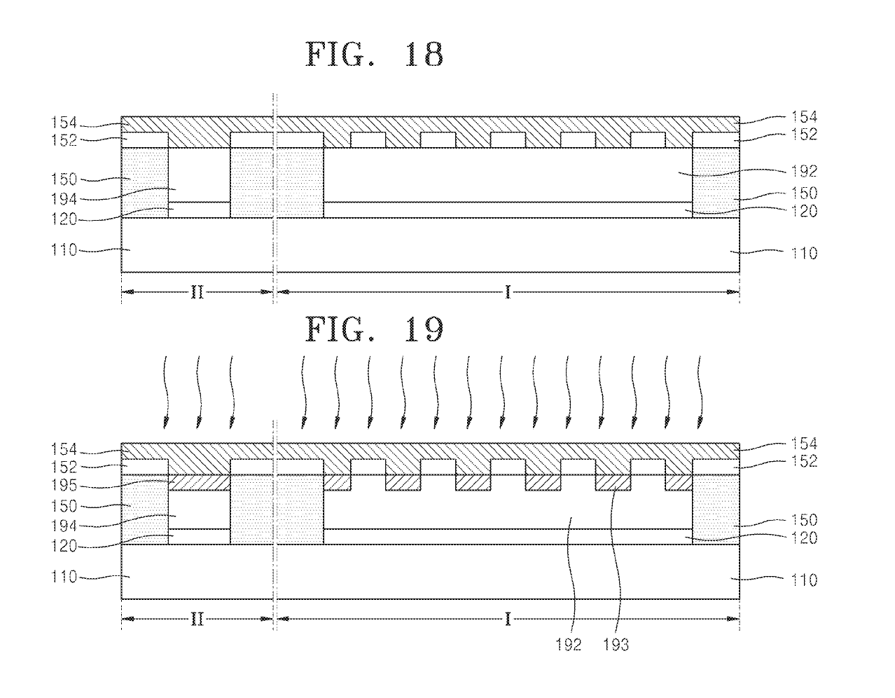

Referring to FIG. 17, a mask pattern 152 is formed on the first doped layer 192 of the first region I and the second doped layer 194 of the second region II. The mask pattern 152 may be formed to expose a part of the first doped layer 192. Also, the mask pattern 152 may be formed to expose a part of the second doped layer 194. Although the mask pattern 152 is formed to expose the entire region of the second doped layer 194 in FIG. 17, this is just an example, and the mask pattern 152 may be formed to expose only a part of the second doped layer 194. The mask pattern 152 may be formed using a photoresist or a hard mask. A surface of the first doped layer 192 exposed by the mask pattern 152 may have a pattern for forming the shapes of portions of the second resistive layer 140 described with reference to, for example, FIGS. 5 to 9.

Referring to FIG. 18, a sacrificial layer 154 is formed on the mask pattern 152. The sacrificial layer 154 may contact surfaces (e.g., top surfaces) of the first doped layer 192 and contact surfaces of the second doped layer 194 that are exposed by the mask pattern 152.

The sacrificial layer 154 may include a conductive material, for example, a metal. The sacrificial layer 154 may include a material that can be used to cause a silicide reaction with the first doped layer 192 and the second doped layer 194. The sacrificial layer 154 may include, for example, at least one of Ti, Co, Ni, Ta, Pt, V, Er, Zr, Hf, Mo, and Yb. The sacrificial layer 154 may be formed by sputtering, CVD, LPCVD, PECVD, ALD, or the like.

Referring to FIG. 19, a first silicide layer 193 is formed on the exposed surface of the first doped layer 192 of the first region I, and/or a second silicide layer 195 is formed on the exposed surface of the second doped layer 194 of the second region II. The first silicide layer 193 may be formed by reaction between the material of the sacrificial layer 154 and the material of the first doped layer 192. For example, the first silicide layer 193 may include a metal silicide material formed by reaction between the metal of the sacrificial layer 154 and the silicon of the first doped layer 192. Also, the second silicide layer 195 may be formed by reaction between the material of the sacrificial layer 154 and the material of the second doped layer 194. For example, the second silicide layer 195 may include a metal silicide material formed by reaction between the metal of the sacrificial layer 154 and the silicon of the second doped layer 194. The first silicide layer 193 and the second silicide layer 195 may be formed in the same annealing process or may be individually formed in different annealing processes. The first silicide layer 193 may be disposed on a part of the first doped layer 192, or the first silicide layer 193 and the first doped layer 192 may be alternately formed. In other words, the first doped layer 192 may be disposed to contact a bottom surface and lateral surfaces of the first silicide layer 193. The second doped layer 194 may be disposed to contact a bottom surface of the second silicide layer 195.

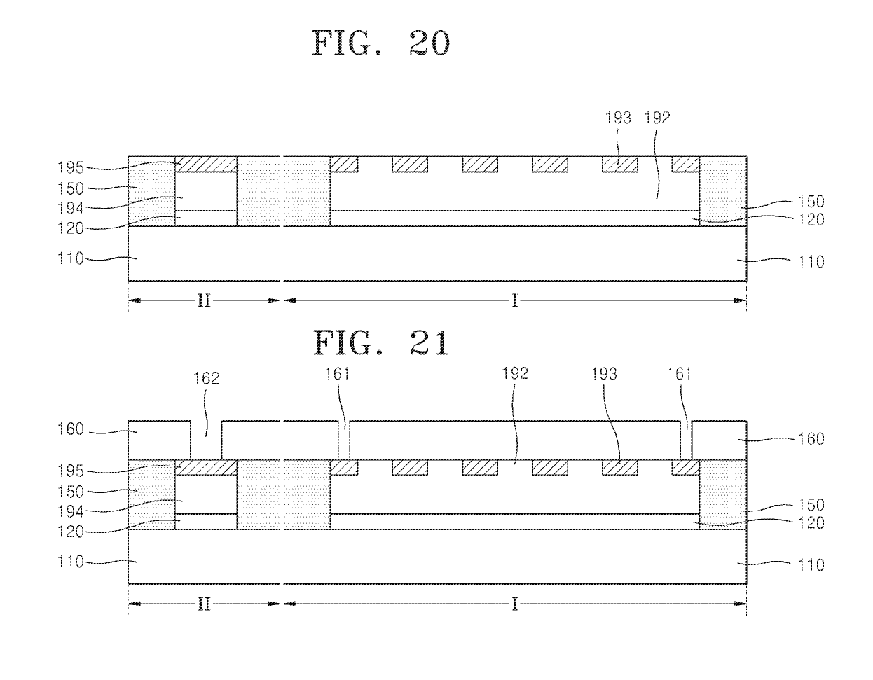

Referring to FIG. 20, the first silicide layer 193 of the first region I and the second silicide layer 195 of the second region II are exposed by removing the mask pattern 152 and the sacrificial layer 154. The removing process may be performed by using a planarization process such as chemical mechanical polishing or an etching process (e.g., an etch back process). In the first region I, the first silicide layer 193 may be partially formed in an upper region of the first doped layer 192. Also, the first silicide layer 193 and the first doped layer 192 may be alternately formed. The surface (e.g., a top surface) of the first doped layer 192 and a surface (e.g., a top surface) of the first silicide layer 193 may be on the same plane. In the second region II, the second silicide layer 195 may be formed in an upper portion of the second doped layer 194. Also, the second doped layer 194 may be disposed below the second silicide layer 195.

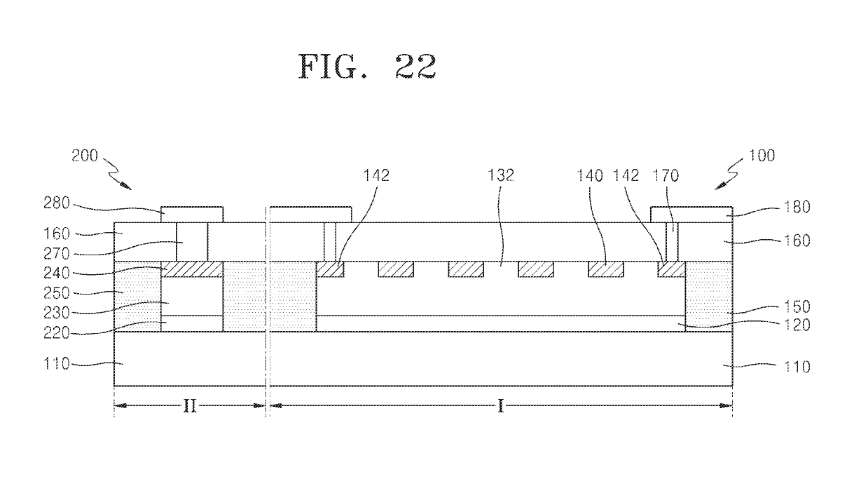

Referring to FIG. 21, the third insulating interlayer 160 is formed to cover the first doped layer 192 and the first silicide layer 193 in the first region I and to cover the second silicide layer 195 in the second region II. The third insulating interlayer 160 may include at least one of oxide, nitride, and oxynitride. Also, the third insulating interlayer 160 may include, for example, at least one of silicon oxide, silicon nitride, and silicon oxynitride. The first insulating interlayer 120, the second insulating interlayer 150, and/or the third insulating interlayer 160 may include the same material or different materials. Then, a first opening 161 and a second opening 162 are formed in the first region I and the second region II, respectively, by removing a part of the third insulating interlayer 160. The first opening 161 may expose the first silicide layers 193 disposed at two ends. The second opening 162 may expose the second silicide layer 195.

Referring to FIG. 22, a first conductive plug 170 is formed to fill the first opening 161 and to be physically and/or electrically connected to the first silicide layers 193 in the first region I. The first conductive plug 170 penetrates the third insulating interlayer 160 in the first region I. Also, a second conductive plug 270 is formed to fill the second opening 162 and to be physically and/or electrically connected to the second silicide layer 195 in the second region II. The second conductive plug 270 penetrates the third insulating interlayer 160 in the second region II. The first conductive plug 170 and the second conductive plug 270 include a conductive material, for example, a metal such as Al, Cu, W, Ti, or Ta, or an alloy such as TiW or TiAl. The first conductive plug 170 and the second conductive plug 270 may be formed in the same process or in different processes.

Then, a conductive terminal 180 is formed on the third insulating interlayer 160 to be physically and/or electrically connected to the first conductive plug 170 in the first region I. A conductive line 280 is formed on the third insulating interlayer 160 to be physically and/or electrically connected to the second conductive plug 270 in the second region II. The conductive terminal 180 and the conductive line 280 may include a conductive material, for example, a metal such as Al, Cu, W, Ti, or Ta, or an alloy such as TiW or TiAl. The conductive terminal 180 and the conductive line 280 may be formed in the same process or in different processes. The conductive line 280 may be referred to as a bit line, a word line, or an address line.

In the first region I, the first doped layer 192 may correspond to the first resistive layer 130, and the first silicide layer 193 may correspond to the second resistive layer 140. Thus, the manufacture of the resistive device 100, including the first resistive layer 130 and the second resistive layer 140, may be completed in the first region I.

In the second region II, the first insulating interlayer 120 may correspond to a gate insulating layer 220, the second doped layer 194 may correspond to the gate electrode 230, the second silicide layer 195 may correspond to a joining layer 240 connecting the gate electrode 230 and the second conductive plug 270. Thus, the manufacture of a transistor structure 200 may be completed in the second region II.

The silicide reaction performed to form a resistive device according to embodiments of the inventive concept may be performed together with various silicide reactions for forming a transistor structure. For example, as described above, the silicide reaction may be performed together with a silicide process performed when forming a conductive plug connected to a gate electrode. Also, the silicide reaction may be performed together with a silicide process performed when forming a conductive plug connected to a source region or a drain region.

Also, the transistor structure may be a metal-oxide semiconductor (MOS) transistor, a bipolar transistor, or a diode.

According to the resistive device according to the embodiments of the inventive concept, a desired resistance may be obtained by forming a silicide pattern layer on a semiconductor layer. The resistive device includes a first resistive layer formed of a semiconductor layer and a second resistive layer disposed on the first resistive layer, including a silicide material, and having a resistance lower than the first resistive layer. A resistance of the resistive device may vary by forming a silicide pattern layer having any of various shapes, and thus, the resistance of the resistive device may be easily changed.

Also, the silicide pattern layer of the second resistive layer and a silicide layer required in a transistor structure may be formed at the same time, and thus, a mask and other processes are not required, thereby reducing a manufacturing cost and improving a reliability of the resistive device.

According to an aspect of the inventive concept, there is provided a resistive device including: a substrate; a first resistive layer disposed on the substrate; a second resistive layer disposed on a part of the first resistive layer and having a resistance different from that of the first resistive layer; a third resistive layer disposed on two ends of the first resistive layer; a conductive plug electrically connected to the third resistive layer; and a conductive terminal electrically connected to the conductive plug.

A resistance of the entire resistive device may vary by changing the number of second resistive layers and the size of the second resistive layer.

The second resistive layer may include a plurality of regions.

The plurality of regions may have the same size.

One of the plurality of regions and the third resistive layer may have the same size.

The plurality of regions may be spaced apart from one another at equal intervals.

The second resistive layer may include one region.

The second resistive layer may be disposed to contact the third resistive layer.

The second resistive layer may be spaced apart from the third resistive layer.

The resistive device may further include an insulating interlayer between the substrate and the first resistive layer.

A top surface of the first resistive layer and a top surface of the second resistive layer may be on the same plane.

A resistance of the second resistive layer may be lower than that of the first resistive layer, and a resistance of the third resistive layer may be the same as that of the second resistive layer.

The second resistive layer may include a metal silicide material.

The first resistive layer may be doped with an n-type conductive material or a p-type conductive material.

The first resistive layer may include at least one selected from the group consisting of silicon, silicon-germanium, and germanium.

According to another aspect of the inventive concept, there is provided a resistive device array including a plurality of resistive devices each including: a substrate; a first resistive layer disposed on the substrate; a second resistive layer disposed on a part of the first resistive layer and having a resistance different from that of the first resistive layer; a third resistive layer disposed on two ends of the first resistive layer; a conductive plug electrically connected to the third resistive layer; and a conductive terminal electrically connected to the conductive plug.

The plurality of resistive devices may be connected to one another in series.

The plurality of resistive devices may be connected to one another in parallel.

A resistance of the second resistive layer may be lower than that of the first resistive layer, and a resistance of the third resistive layer may be the same as that of the second resistive layer.

According to another aspect of the inventive concept, there is provided a method of manufacturing a resistive device, the method including: forming a first insulating interlayer on a substrate; forming a semiconductor layer on the first insulating interlayer; forming a doped layer by doping the semiconductor layer with impurities; forming a mask pattern on the doped layer to expose a part of the doped layer; forming a sacrificial layer on a part of the doped layer exposed by the mask pattern; forming a first resistive layer and a second resistive layer from the doped layer by forming a silicide material by reacting the doped layer with the sacrificial layer via annealing, wherein the second resistive layer includes the silicide material and has a resistance lower than that of the first resistive layer; and removing the mask pattern and the sacrificial layer; and forming a conductive terminal to be electrically connected to the second resistive layer.

While the inventive concept has been particularly shown and described with reference to exemplary embodiments thereof, it will be understood that various changes in form and details may be made therein without departing from the spirit and scope of the following claims.

What is claimed is:

1. A resistive device comprising:
a substrate;
a first resistive layer disposed above the substrate;
a second resistive layer disposed on the first resistive layer and having a resistance different from a resistance of the first resistive layer;
a third resistive layer disposed on a first portion of the first resistive layer such that a second portion of the first resistive layer is disposed between the third resistive layer and the second resistive layer; and
a conductive plug electrically connected to the third resistive layer.

2. The resistive device of claim 1, wherein a resistance of the resistive device is defined by at least one of a number of portions of the second resistive layer or a surface area of the second resistive layer.

3. The resistive device of claim 1, wherein the second resistive layer includes a plurality of portions.

4. The resistive device of claim 3, wherein the first resistive layer has a top surface aligned a long a plane within which a top surface of the second resistive layer is aligned, each portion from the plurality of portions included in the second resistive layer has a surface area, which is aligned along the plane, that is the same.

5. The resistive device of claim 3, wherein one portion from the plurality of portions included in the second resistive layer has a surface area equal to a surface area of the third resistive layer.

6. The resistive device of claim 3, wherein portions from the plurality of portions included in the second resistive layer are spaced at equal intervals within the first resistive layer.

7. The resistive device of claim 1, wherein the second resistive layer includes one portion.

8. The resistive device of claim 1, wherein the second resistive layer includes one portion, the second resistive layer is in contact with a portion of the third resistive layer.

9. The resistive device of claim 1, wherein the second resistive layer includes one portion, the second resistive layer is separated from the third resistive layer by at least the second portion of the first resistive layer disposed between the second resistive layer and the third resistive layer.

10. The resistive device of claim 1, further comprising an insulating interlayer vertically disposed between the substrate and the first resistive layer.

11. The resistive device of claim 1, wherein a top surface of the first resistive layer and a top surface of the second resistive layer are aligned along the same plane.

12. The resistive device of claim 1, wherein a resistance of the second resistive layer is lower than a resistance of the first resistive layer, and a resistance of the third resistive layer is the same as a resistance of the second resistive layer.

13. The resistive device of claim 1, wherein the second resistive layer includes a metal silicide material.

14. The resistive device of claim 1, wherein the first resistive layer is doped with an n-type conductive material or a p-type conductive material.

15. The resistive device of claim 1, wherein the first resistive layer includes at least one of silicon, silicon-germanium, and germanium.

16. A resistive device array, comprising:
a plurality of resistive devices, each resistive device from the plurality of resistive devices including:
a substrate,
a first resistive layer disposed on the substrate,
a second resistive layer defined within the first resistive layer and having a resistance different from that of the first resistive layer,
a third resistive layer having a first portion disposed within a first edge portion of the first resistive layer and having a second portion disposed within a second edge portion of the first resistive layer, and
a conductive plug electrically connected to the first portion of the third resistive layer.

17. The resistive device array of claim 16, wherein the plurality of resistive devices includes a first resistive device connected to a second resistive device from the plurality of resistive devices in series.

18. The resistive device array of claim 16, wherein the plurality of resistive devices includes a first resistive device connected to a second resistive device from the plurality of resistive devices in parallel.

19. The resistive device array of claim 16, wherein a resistance of the second resistive layer is lower than a resistance of the first resistive layer, and a resistance of the third resistive layer is the same as a resistance of the second resistive layer.

20. A method of manufacturing a resistive device, comprising:
forming an insulating interlayer on a substrate;
forming a semiconductor layer on the insulating interlayer;
forming a doped layer by doping the semiconductor layer with impurities; and
forming a silicide material within the doped layer such that a first resistive layer is defined within the doped layer by a second resistive layer including the silicide material, the second resistive layer including the silicide material has a resistance lower than a resistance of the first resistive layer.

21. The method of claim 20, wherein the first resistive layer includes portions interleaved within portions of the second resistive layer.

22. The method of claim 20, wherein the first resistive layer has a top surface that is coplanar with a top surface of the second resistive layer.

23. The method of claim 20, further comprising:
forming a mask pattern on the doped layer such that at least a portion of the doped layer is exposed;
forming a sacrificial layer on the portion of the doped layer exposed through the mask pattern; and
removing the mask pattern and the sacrificial layer.
